(19) United States
(12) Patent Application Publication
(10) Pub. No.: US 2025/0138228 A1
(43) Pub. Date: May 1, 2025

(54) MIRROR FOR A PROJECTION EXPOSURE APPARATUS

(71) Applicant: Carl Zeiss SMT GmbH, Oberkochen (DE)

(72) Inventors: Valentin Jonatan Bolsinger, Aalen (DE); Sandro Hoffmann, Giengen an der Brenz (DE)

(21) Appl. No.: 19/011,435

(22) Filed: Jan. 6, 2025

Related U.S. Application Data
(63) Continuation of application No. PCT/EP2023/068705, filed on Jul. 6, 2023.

(30) Foreign Application Priority Data
Jul. 11, 2022 (DE) 10 2022 207 052.6

(51) Int. Cl. G02B 5/18; G02B 5/20; G02B 5/26; G03F 7/00

(52) U.S. Cl. CPC G02B 5/1814; G02B 5/1861; G02B 5/208; G02B 5/26; G03F 7/70033; G03F 7/7015; G03F 7/702; G03F 7/70233; G03F 7/70316

(57) ABSTRACT

A mirror for a projection exposure apparatus has a spectral filter, embodied as a grating structure, for light reflected by the mirror. The grating structure has at least two grating levels and hence specifies at least two optical path lengths for the reflected light. An overall flank portion of the grating structure is arranged in each case between grating level structure portions of the grating structure, which each specify adjacent grating levels. A lower limit spatial wavelength over a defect-free partial flank portion of the overall flank portion making up at least an extent of 90% of the overall flank portion is in the range from 0.01 μm to 1 μm exclusive.

### CROSS-REFERENCE TO RELATED APPLICATIONS

The present application is a continuation of, and claims benefit under 35 USC 120 to, international application No. PCT/EP2023/068705, filed Jul. 6, 2023, which claims benefit under 35 USC 119 of German Application No. 10 2022 207 052.6, filed Jul. 11, 2022. The entire disclosure of each of these applications is incorporated by reference herein.

### FIELD

The disclosure relates to a mirror for a projection exposure apparatus. Further, the disclosure relates to an illumination optical unit having such a mirror, to an optical system having such an illumination optical unit, to an illumination system having such an illumination optical unit, to a projection exposure apparatus having such an optical system, to a method for producing a microstructured or nanostructured component and to a component produced by this method.

### BACKGROUND

Mirrors of the type set forth at the outset are known from DE 10 2018 220 629 A1, WO 2017/207 401 A1 and DE 10 2012 010 093 A1. DE 10 2018 202 629 A1 discloses a mirror for an illumination optics of a projection exposure apparatus having a spectral filter embodied as a grating structure. DE 10 2010 030 913 A1 discloses a method to produce a substrate for an EUV mirror having a given surface form at a temperature of use.

### SUMMARY

The present disclosure seeks to develop a mirror having improved service life.

In an aspect, the disclosure provides a mirror for a projection exposure apparatus. The mirror has a spectral filter, embodied as a grating structure, for light reflected by the mirror. The grating structure specifies at least two grating levels and hence specifies at least two optical path lengths for the reflected light. An overall flank portion of the grating structure is arranged in each case between grating level structure portions of the grating structure, which each specify adjacent grating levels. A lower limit spatial wavelength over a defect-free partial flank portion of the overall flank portion making up at least an extent of 90% of the overall flank portion between the adjacent grating level structure portions is in the range from 0.01 μm to 1 μm exclusive. An upper limit spatial wavelength over the defect-free partial flank portion of the overall flank portion is in the range from 0.1 micrometer (μm) to 100 μm exclusive. An effective roughness of the defect-free partial flank portion above the lower limit spatial wavelength and below the upper limit spatial wavelength is less than 10 nanometers (nm). The mirror has a protective layer on the grating structure.

According to the disclosure, it was recognized that an effective roughness of a flank portion of a grating structure used for spectral filtering purposes on the mirror influences the durability of a protective layer on the grating structure. Care is to be taken that the flank portion to have a small effective roughness, especially above spatial wavelengths in the range from 0.01 μm to 1 μm exclusive, so that an improved durability of the protective layer can help be ensured. It was found that a smoothness of the defect-free partial flank portion and a corresponding smoothness of a protective layer that can then be applied thereto can have a positive effect on the durability of the protective layer, and hence on the service life of the mirror. In this case, structure effects and greater roughnesses can be tolerated over a certain range of the overall flank portion provided that the roughness specification is ensured within the defect-free partial flank portion. The lower limit spatial wavelength, above which the roughness specification is to be met, may be in the range from 0.01 μm to 0.2 μm exclusive, depending on the embodiment of the grating structure. The upper limit spatial wavelength, below which the roughness specification should be met, may be in the range from 0.1 μm to 10 μm exclusive.

Reference is made to WO 2017/207 401 A1 regarding the definition for the “limit spatial wavelength” and “effective roughness” parameters.

The mirror can be an EUV collector.

The mirror can be a constituent part of a source collector module, can be a constituent part of an illumination optical unit or can otherwise be a constituent part of a projection optical unit of an illumination apparatus.

An effective roughness of the defect-free partial flank portion above the lower limit spatial wavelength can be less than 3 nm. Such more stringent roughness demands can lead to a further increase in the mirror service life. The effective roughness above the lower limit spatial wavelength can be less than 1 nm and can also be less than 0.3 nm.

The defect-free partial flank portion can have an extent of more than 95% of the overall flank portion between the adjacent grating level structure portions. To the extent that such a defect-free partial flank portion contains more than 95% of the overall flank portion, there can be a correspondingly improved substrate adhesion and, in this way, a further improved mirror service life. The overall flank portion can meet the specified roughness demands in full, with the result that the defect-free partial flank portion coincides with the overall flank portion.

In some embodiments, a maximum slope variation as measured at structures of the defect-free partial flank portion is no more than 200°/μm. Such a slope variation specification can lead to a further roughness characterization, by means of which a service life-lengthening design of the flank portion of the grating structure is obtained. The maximum slope variation may be no more than 150° per μm, may be no more than 100° per μm, may be no more than 50° per μm or else may be no more than 25° per μm, for example 20° per μm.

Further roughness specifications may arise by specifying limit values for a second derivative of a defect structure with respect to at least one spatial coordinate.

The defect-free partial flank portion can be manufactured by a subtractive method and/or by an additive method. Such manufacturing methods for the defect-free partial flank portion can lead to effective smoothing of this partial flank portion, and hence to the roughness specifications being satisfied. A chemical and/or physical process, a local and/or global laser ablation, a polishing method or else an additive method, for example on the basis of a coating, may be used as the smoothing method.

Features of related illumination optical units, related optical systems, related illumination systems, related projection exposure apparatus, related production methods, and related microstructured or nanostructured component parts can correspond to those which have already been discussed above with reference to the mirror.

For example, a semiconductor component, for example a memory chip, can be produced using the projection exposure apparatus.

### BRIEF DESCRIPTION OF THE DRAWINGS

Further features and details of the disclosure are evident from the description of a plurality of exemplary embodiments with reference to the drawings, in which:

FIG. 1 schematically shows a meridional section through a projection exposure apparatus for EUV projection lithography;

FIG. 2 shows a schematic illustration of a mirror having a spectral filter in the form of a coated grating structure;

FIG. 3 schematically shows a section of the coated grating structure in the region of a flank of a further embodiment of a coated grating structure;

FIG. 4 perspectively shows a section of the grating structure, approximately corresponding to FIG. 3, prior to a coating with two grating level structure portions and an interposed overall flank portion;

FIG. 5 shows an enlarged excerpt of the detail V in FIG. 4 for the purpose of illustrating a micro-roughness of the overall flank portion;

FIG. 6 shows a cross section through the uncoated grating structure according to FIG. 4 for the purpose of illustrating a subtractive smoothing method;

FIG. 7 shows a cross section through the uncoated grating structure according to FIG. 4 for the purpose of illustrating an additive smoothing method;

FIG. 8 shows an overview of diagrammatic representations for the purpose of illustrating roughness parameters of a defect-free overall flank portion of the grating structure according to FIG. 4;

FIG. 9 shows, in an overview similar to FIG. 8, corresponding diagrammatic representations for the roughness parameters of an example for a “rounded-off particle on the overall flank portion” defect;

FIG. 10 shows, in an overview similar to FIG. 8, corresponding diagrammatic representations for the roughness parameters of an example for an “edge contour particle on the overall flank portion” defect;

FIG. 11 shows, in an overview similar to FIG. 8, corresponding diagrammatic representations for the roughness parameters of an example for a “scratch with an edge contour in the overall flank portion” defect;

FIG. 12 shows, in an overview similar to FIG. 8, corresponding diagrammatic representations for the roughness parameters of an example for a “rounded-off depression in the overall flank portion” defect; and

FIG. 13 shows, in an overview similar to FIG. 8, corresponding diagrammatic representations for the roughness parameters of an example for a “statistical roughness on the overall flank portion” defect.

### DETAILED DESCRIPTION

Firstly, the general construction of a microlithographic projection exposure apparatus 1 will be described.

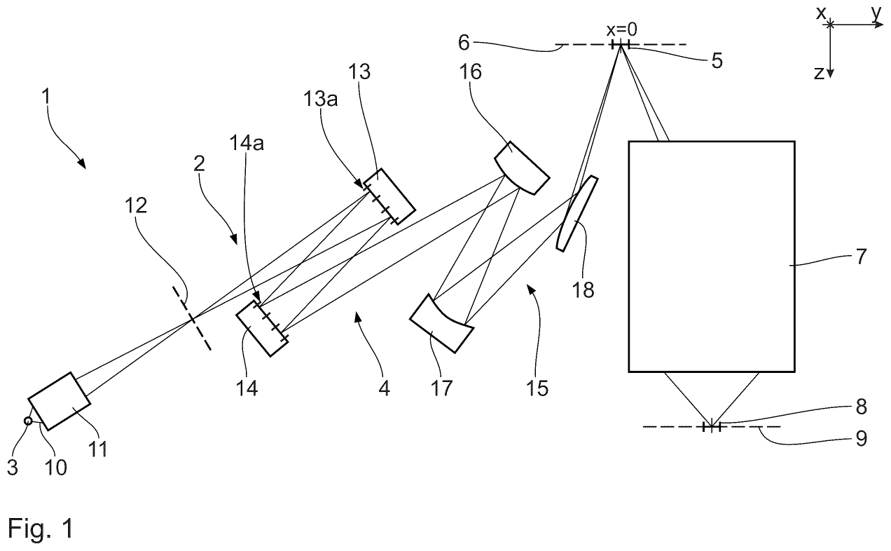

FIG. 1 schematically shows a meridional section of a microlithographic projection exposure apparatus 1. An illumination system 2 of the projection exposure apparatus 1 has, besides a radiation source 3 or light source 3, an illumination optical unit 4 for the exposure of an object field 5 in an object plane 6. In this case, a reticle (not illustrated in the drawing) that is arranged in the object field 5 and is held by a reticle holder (likewise not illustrated) is exposed. A projection optical unit 7 serves for imaging the object field 5 into an image field 8 in an image plane 9. A structure on the reticle is imaged onto a light-sensitive layer of a wafer (likewise not illustrated in the drawing) that is arranged in the region of the image field 8 in the image plane 9 and is held by a wafer holder (likewise not illustrated).

The radiation source 3 is an EUV radiation source with emitted used radiation in the range of between 5 nm and 30 nm. This may be a plasma source, for example a GDPP (gas discharge-produced plasma) source or an LPP (laser-produced plasma) source. By way of example, tin can be excited to form a plasma by means of a carbon dioxide laser operating at a wavelength of 10.6 μm, that is to say in the infrared range. A radiation source based on a synchrotron can also be used for the radiation source 3. A person skilled in the art can find information relating to such a radiation source for example in U.S. Pat. No. 6,859,515 B2. EUV radiation 10 emerging from the radiation source 3 is focused by a collector 11. A corresponding collector is known from EP 1 225 481 A. Downstream of the collector 11, the EUV radiation 10 propagates through an intermediate focal plane 12 before being incident on a field facet mirror 13 with a multiplicity of field facets 13a. The field facet mirror 13 is arranged in a plane of the illumination optical unit 4 which is optically conjugate with respect to the object plane 6.

The EUV radiation 10 is also referred to hereinafter as illumination light or as imaging light.

Downstream of the field facet mirror 13, the EUV radiation 10 is reflected by a pupil facet mirror 14 with a multiplicity of pupil facets 14a. The pupil facet mirror 14 is arranged in a pupil plane of the illumination optical unit 4, which is optically conjugate with respect to a pupil plane of the projection optical unit 7. With the aid of the pupil facet mirror 14 and an imaging optical assembly in the form of a transfer optical unit 15 having mirrors 16, 17 and 18 designated in the order of the beam path, field individual facets 13a of the field facet mirror 13, which are also referred to as subfields or as individual-mirror groups and are described in even greater detail below, are imaged into the object field 5. The last mirror 18 of the transfer optical unit 15 is a grazing incidence mirror.

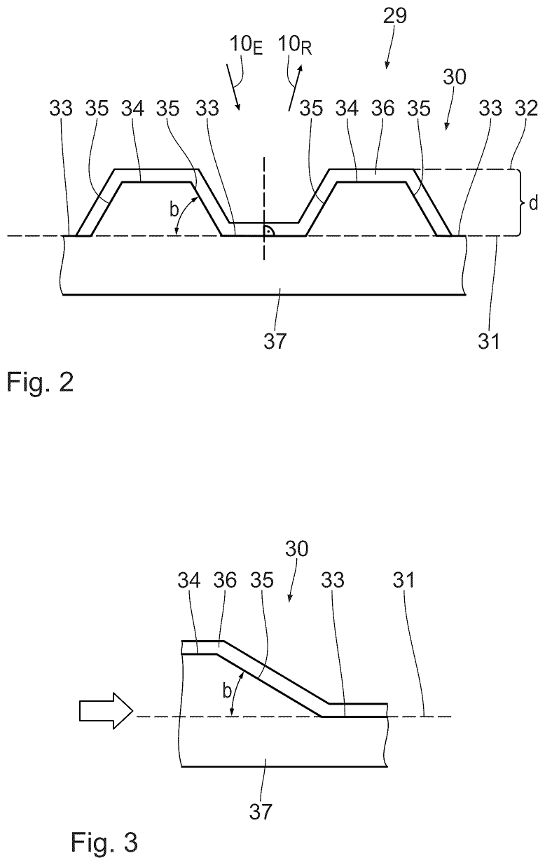

FIG. 2 illustrates by way of example and schematically a portion of a reflection surface of a mirror 29 having a spectral filter in the form of a grating structure 30. The mirror 29 can be a collector, a mirror of the illumination optical unit 4 and/or a mirror of the projection optical unit 7.

The grating structure 30 serves as a spectral filter for masking out radiation having wavelengths in a predefined range, for example for masking out wavelengths in the infrared range, by way of diffraction. The masked radiation at wavelengths which differ from the used light wavelength reflected by the mirror 29 is also referred to as stray light.

The grating structure 30 has two grating levels, namely a lower grating level 31 and an upper grating level 32. For incident illumination or imaging light 10E, the grating structure 30, by way of these two grating levels 31, 32, specifies two optical path lengths for the respective reflected illumination or imaging light 10R. Depending on the embodiment of the grating structure 30, the latter may also have more than two grating levels, with the result that, for example, it is also possible to specify more than two different optical path lengths for the respective reflected illumination or imaging light 10R.

The lower grating level 31 is specified by lower grating level structure portions 33, flush therewith, of the grating 30. The upper grating level 32 is specified by upper grating level structure portions 34 of the grating structure 30.

An overall flank portion 35 of the grating structure 30 is arranged in each case between the grating level structure portions 33, 34 or 34, 33, which each specify adjacent grating levels 31, 32 or 32, 31. Between the overall flank portion 35 and the lower grating level 31 is a smallest flank angle b, which is less than 90° and regularly is between 5° and 80°, for example in the range from 10° to 70° exclusive or else in the range from 30° to 60° exclusive.

FIG. 3 shows a variant of the grating structure 30 with a smaller flank angle b of the overall flank portion 35 with respect to the lower grating level 31 than in the case of the embodiment according to FIG. 2.

On account of the flank angle b differing from 90°, the grating structure 30 in each case has a trapezium-shaped cross section for example. The cross section may correspond to an isosceles trapezium. It is non-rectangular, for example.

The percentage of the area of the overall reflection surface area of the mirror 29, for example of the overall area of the grating structure 30, which is constituted by the overall flank portions 35, in plan view, for example in perpendicular projection, is no more than 10%, for example no more than 5%, for example no more than 3%, for example no more than 2%, for example no more than 1%, for example no more than 0.5%, for example no more than 0.3%. These area relationships apply for example in a projection along a normal of the overall reflection surface of the mirror 29.

Instead of a trapezium-shaped cross section, the grating structure 30 can generally also have a cross section having a trapezium-shaped smallest envelope. The upper and lower grating level structure portions 34, 33 need not extend parallel to one another.

A level difference d between the lower grating level 31 and the upper grating level 32 may be of the order of a quarter wavelength in the infrared range. This level difference d is, for example, in the range from 1 micrometre to 10 micrometres. Other values are likewise possible.

The level difference d is also referred to as the groove depth of the grating structure 30. For further details, reference should be made to DE 10 2012 010 093 A1.

The grating structure 30 carries a protective layer 36. The flank angle b less than 90° makes it possible to ensure that the protective layer 36 is closed, for example the substrate 37 is covered completely and without gaps. Moreover, this ensures a desirable long service life and, for example, good and permanent adhesion of the protective layer 36 on the grating structure 30, especially in the region of the overall flank portion 35.

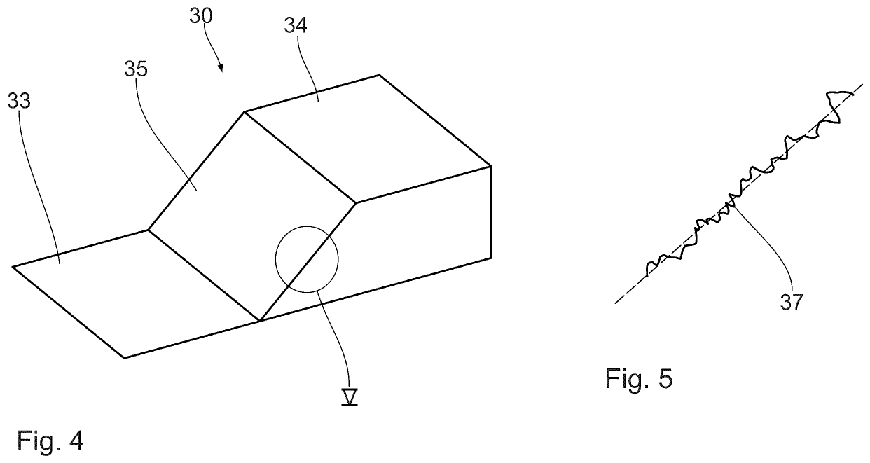

The perspective illustration according to FIG. 4 once again illustrates the structure of the still uncoated grating structure 30 with the lower grating level structure portion 33, the upper grating level structure portion 34 and the interposed overall flank portion 35. An enlarged excerpt V of FIG. 4 in accordance with FIG. 5 illustrates a micro-roughness 37 of the overall flank portion 35.

FIGS. 4 and 5 show the uncoated grating structure 30, which is to say the grating structure 30 before the protective layer 36 has been applied.

The micro-roughness 37 can be described as a surface structure distribution dependent on spatial wavelengths P. Surface structures with spatial wavelengths below a limit spatial wavelength P_{G} are significantly reduced as a result of appropriate surface processing, for example smoothing
or polishing, with the result that the following applies to an effective roughness rms_{G} for spatial wavelengths P below the limit spatial wavelength P_{G}:

$${( 4 π {rms}_{G} cos ( θ ) / λ )}^{2} < 0.1$$

Here, λ is the used EUV wavelength. Here, θ is the angle of incidence of the used EUV light 3 at a mirror surface of the mirror 29.

Apart from the angle of incidence θ, the relation for the effective roughness rms_{G} depends only on the used light wavelength λ. For 2=13.5 nm and θ=0, the following applies: rms_{G}≤0.35 nm.

The effective roughness rms emerges as an integral of a range between two different limit spatial wavelengths. An effective roughness rms_{GG′} of the mirror surface above the lower limit spatial wavelength P_{G} and optionally below an upper limit spatial wavelength P_{G′}, which is to say between the lower and the upper limit spatial wavelength, is at least one and a half times greater, but no more than six times greater, than below the lower limit spatial wavelength P_{G}.

An effective roughness rms_{GG′} of the order of 0.5 nm, with 0.5 nm representing a lower limit for this effective roughness, can be present in a region around the lower limit spatial wavelength P_{G}. An effective roughness rms_{GG′} of the order of 2 nm, with 2 nm representing the upper limit of this effective roughness, can be present in a region around the upper limit spatial wavelength P_{G′}.

The polish of the mirror surface at spatial wavelengths below the limit spatial wavelength P_{G} can be such that these spatial wavelengths practically do not contribute to a spectral power density (PSD).

The spectral power density PSD is specified in units of [nm⁴]. Details regarding the definition of the spectral power density are found in the textbook “Optical Scattering: Measurement and Analysis” by John C. Stover, SPIE, 2nd edition 1995 and 3rd edition 2012, and in the article “Power Spectral Density (PSD)” on the Internet pages of www.nanophys.kth.se, retrievable on 22 Jan. 2016.

A measurement method for, firstly, the spectral power density PSD and, secondly, the effective roughness rms can be gathered from the article “Surface characterization techniques for determining the root-mean-square roughness and power spectral densities of optical components” by Duparré et al., Applied Optics, volume 41, number 1, 01.01.2002. Various items of measurement equipment are discussed in the section “3. Instruments” in this article. The section “4. Calculation of the Power Spectral Density Function and the rms roughness” of this article specifies how, firstly, the spectral power density PSD and, secondly, the effective roughness rms, referred to there as σᵣₘₛ, are calculated from the obtained measurement data.

The respective rms values for the effective roughness emerge from the PSD on the basis of the following relationship:

$${rms}^{2} = 2 \cdot {\int }_{f 1}^{f 2} 2 π f \cdot PSD ( f ) \cdot df$$

The effective roughness rms_{G}, for example in the region of the lower limit spatial wavelength P_{G}, emerges from this relationship by the choice of integration limits f1=1/P_{G} and f2=1/λ_{EUV}. Here, λ_{EUV} is the EUV used wavelength.

With regards to further details in the context of the effective roughness, reference is made to WO2017/207 401 A1.

In the case of the grating structure 30, the lower limit spatial wavelength P_{G} over a defect-free partial flank portion making up at least an extent of 90% of the overall flank portion 35 between the adjacent grating level structure portions 33, 34 is in the range from 0.01 μm to 1 μm exclusive. Thus, a higher lower limit spatial wavelength, for example, can be tolerated in a region extending over no more than 10% of the overall flank portion 35.

The effective roughness rms_{G} of the defect-free partial flank portion of the overall flank portion 35 is less than 10 nm. In grossly simplified terms, this effective roughness can be understood to be a deviation from an ideal structure which connects the two grating levels 31, 32 between the grating level structure portions 33, 34 linearly.

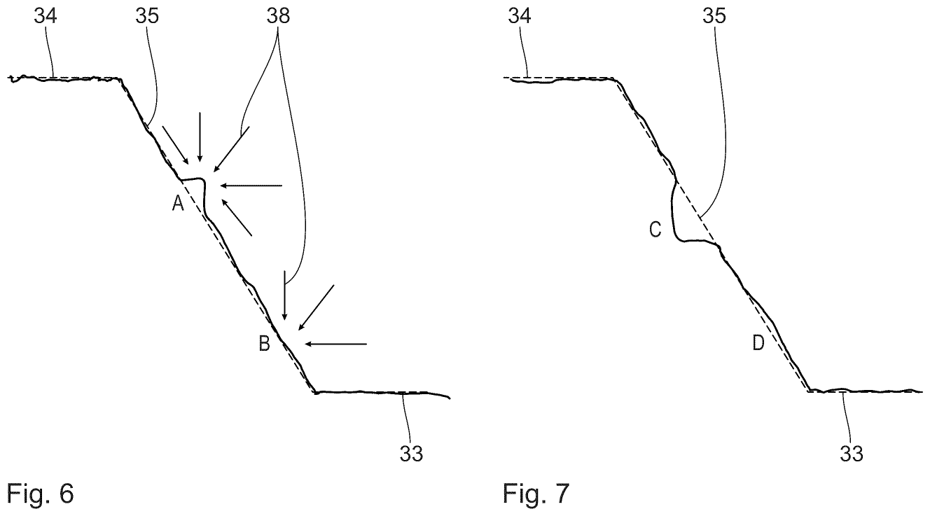

A subtractive smoothing method and/or an additive smoothing method can be used to produce the defect-free partial flank portion of the overall flank portion 35, as explained hereinafter on the basis of FIGS. 6 and 7.

Exposed or convex defects on the overall flank portion 35 are exposed to stronger chemical or physical reactions during an ablation process, for example a chemical and/or physical process or local or global laser ablation, with the assumption being made here that an etching rate acts at least substantially isotropically. Accordingly, more etching components, which is to say chemical molecules or ions for example, act on a defect A (cf. FIG. 6), as is indicated in FIG. 6 by etching action arrows 38. Accordingly, fewer such etching components act on a comparison site B. Thus, more material of the mirror substrate of the grating structure 30 is ablated at the defect A than in its surroundings, leading to a smoothing of the exposed defect A. A corresponding statement applies to a polishing method as an example for a subtractive smoothing method of the overall flank portion 35. The exposed defect A experiences stronger abrasion during polishing than the comparison site B. In this case, a polishing means can act as an imparting polishing component.

In the additive method, concave defects C (cf. FIG. 7) are smoothed by means of a coating. Depending on the available energy of utilized coating particles, these may migrate over the surface of the overall flank portion 35 and can accumulate in concave defect structures in accordance with the defect C. Such concave defect structures then fill quicker with coating particles during the additive smoothing method than a coating of the remaining surface of the overall flank portion 35 (cf. comparison portion D in this case).

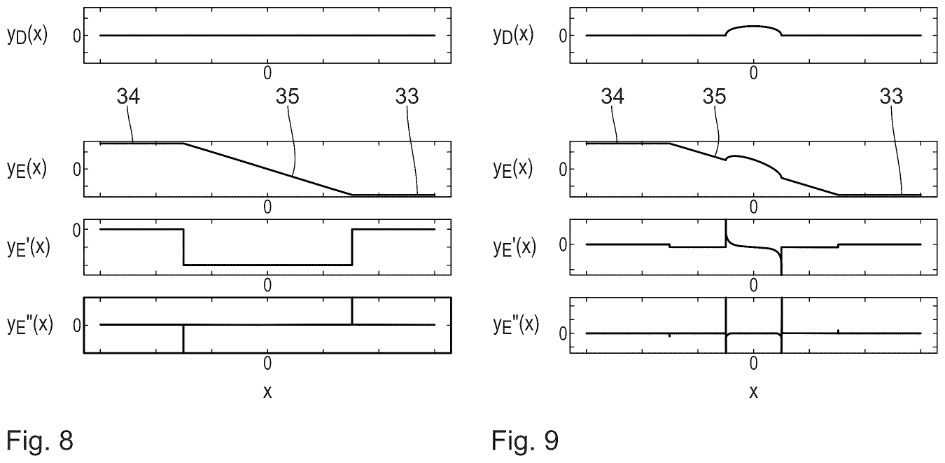

Different defect examples on the overall flank portion 35 are discussed on the basis of their roughness parameters using FIGS. 8 to 13. Each of FIGS. 8 to 13 is subdivided into four diagrams as a function of a spatial coordinate x, depicted over one another. The uppermost diagram shows a defect extent y_{D}(x). The diagram directly below shows the profile of a structure coordinate y_{E}(x) of the grating structure, which is to say of the overall flank portion 35 for example. The diagram directly below that shows a first derivative y_{E}′ (x) of the grating structure profile. The lowermost diagram in FIGS. 8 to 13 shows the second derivative y_{E}″(x) of the grating structure profile.

FIG. 8 shows the ideal case of a defect-free overall flank portion 35. The latter extends between the x coordinates of −3 and +3, specified in arbitrary units. The first derivative y′ varies between 0 at the grating level structure portions 33 and 34 and −1 in the region of the overall flank portion 35. This corresponds to a flank angle b of 45°.

For example, a target criterion in relation to the derivative y′ usable to establish a defect freedom of the respective flank portion may be that, with reference to real defect structure dimensions, a maximum slope variation of the defect structure, measured in ° per path section Delta x along the overall flank portion 35 is less than 200° per μm. A lower limit value may also be specified, for example 150° per μm, 100° per μm, 75° per μm, 50° per μm, 30° per μm, 25° per μm or 20° per μm. These values relate to the values of the spatial frequencies or spatial wavelengths specified above.

The second derivative y″ has a negative or positive quasi singularity in the edge transition region between the upper grating level structure portion 34 and the overall flank portion 35 on the one hand and the overall flank portion 35 and the lower grating level structure portion 33 on the other hand, respectively at the x coordinates −3 and 3.

The conditions specified above for the first derivative y′ and/or the second derivative y″ need not be present over the entire grating structure 30. For example, it is sufficient for these derivative conditions to be satisfied for a defect-free partial flank portion which has an extent of at least 90% of the overall flank portion 35. This extent of the defect-free partial flank portion may also be greater and may be 95% of the overall flank portion 35, for example.

The defect examples below are depicted with much exaggeration in FIG. 9ff.

In the case of the “rounded-off particle” defect example as an example of a convex defect, which is to say a defect protruding beyond the rest of the flank portion, according to FIG. 9, large first derivatives of the order of the absolute value 10 in terms of absolute value are present in each case at the x-coordinates bounding the defect particle. By way of an upper limit value for the absolute value of this first derivative in the range from 3 to 5 exclusive, for example, it is possible to specify a target value for smoothing this defect example of “rounded-off particle” which is to be achieved within the scope of smoothing so that an x-coordinate range occupied by the original particle defect also belongs to the defect-free partial flank portion.

There are very large absolute values of the second derivative, which reach maximum values of approximately 1500, present in the region of the edge transition in the defect example according to FIG. 9. To specify target values for a successful smoothing method, an upper limit value, for example of the order of 500, can also be specified for the second derivative. In this case, the absolute limit value for concave defect structure can be assumed to be higher than for a convex defect structure since the assumption can be made that the protective layer 36 adheres better to concave defect structures than to convex defect structures.

Thus, a higher limit value of the order of 500 can also be tolerated for positive values of the second derivative y″, whereas a lower limit value of the order of 300 can be slated for negative values.

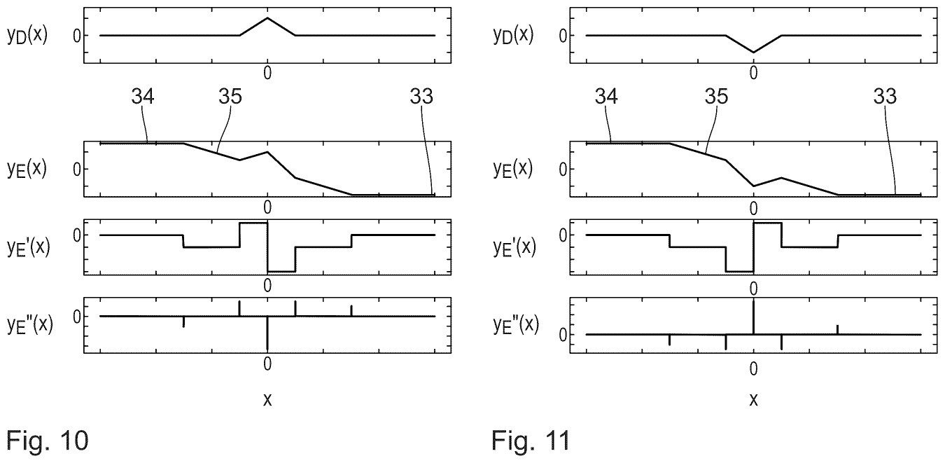

FIG. 10 shows corresponding values for the “particle with edge cross section contour” particle example. This type of defect leads to comparatively small absolute values of the first derivative.

The absolute values of the second derivative y″ are also smaller in the likewise convex “particle with edge-shaped cross section” defect example according to FIG. 10 than in the example according to FIG. 9. With regard to the above-defined target values for the first derivative y′ and the second derivative y″, only the direct convex edge region of the defect example according to FIG. 10 is outside of the specification, and so a defect freedom also in the region of this defect structure can be obtained with the aid of comparatively moderate smoothing ablation in this edge region x=0.

FIG. 11 shows the “scratch” defect example, which is to say a concave defect which represents a depression within the surrounding flank portion, with an approximately triangular cross section in the example according to FIG. 11. What was explained above in the context of the defect examples according to FIGS. 9 and 10 and, for example, in relation to the defect example according to FIG. 10 applies correspondingly here. Since higher tolerance limits than present therein can be set in the case of the concave defect according to FIG. 11, especially in the range of the second derivative y″, the defect according to FIG. 11 can be tolerated and optionally involves no smoothing.

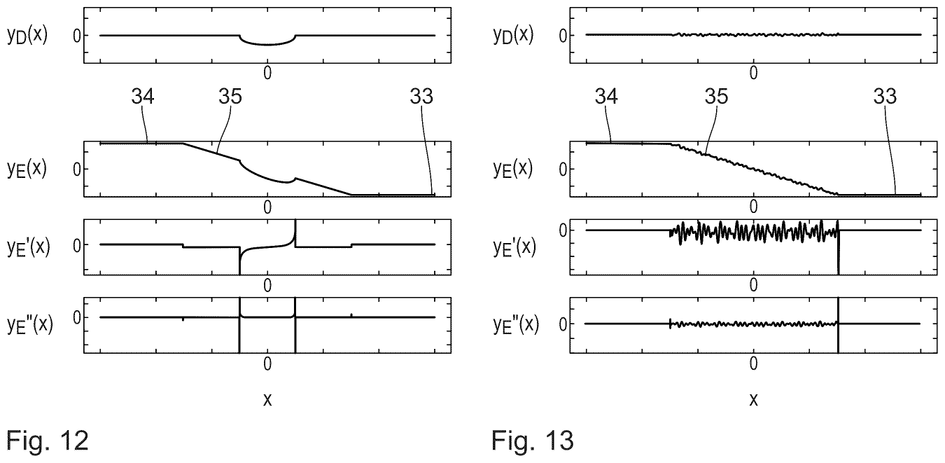

Derivative data corresponding in terms of absolute values to the defect example according to FIG. 9 arise in the “channel” defect example according to FIG. 12. In the edge regions of the defect according to FIG. 12, the derivatives y′ and y″ exhibit large values which would have to be removed by way of an appropriate additive smoothing method so that the defect according to FIG. 12 becomes part of a defect-free partial flank portion.

FIG. 13 shows the “statistical micro-roughness” defect example. In part excessively large values for the derivatives y′ and y″ arise here, which have to be removed by corresponding smoothing methods so that a correspondingly large portion of the overall flank portion is reworked onto the defect-free partial flank portion which attains the smoothing target values.

After the structuring and smoothing of the substrate, the grating structure 30 is provided with the closed protective layer 36. The protective layer 36 is applied to the mirror substrate and can be deposited on the mirror substrate. It is also possible to allow the protective layer 36 to grow on the mirror substrate.

For example, a molybdenum-silicon double-ply structure can serve as the protective layer 36. Details of such a layer stack are known from the prior art.

With the aid of the projection exposure apparatus 1, at least one part of the reticle in the object field 5 is imaged onto a region of a light-sensitive layer on the wafer in the image field 8 for the lithographic production of a microstructured or nanostructured component, for example of a semiconductor component, for example of a microchip. Depending on the embodiment of the projection exposure apparatus 1 as a scanner or as a stepper, the reticle and the wafer are moved in a temporally synchronized manner, continuously in scanner operation or step by step in stepper operation.

What is claimed is:

1. A mirror, comprising:
a spectral filter configured as a grating structure for light reflected by the mirror; and
a protective layer supported by the grating structure,
wherein:
the grating structure comprises first and second grating levels specifying first and second optical path lengths for the reflected light;
the grating structure comprises a plurality of overall flank portions, a plurality of first grating level portions at the first grating level, and a plurality of second grating level portions at the second grating level;
each overall flank portion is between corresponding first and second grating level structure portions;
each overall flank portion comprises a defect-free partial flank portion making up at least 90% of an extent of the overall flank portion;
a lower limit spatial wavelength over each defect-free partial flank portion is exclusively from 0.01 μm to 1 μm;
an upper limit spatial wavelength over each defect-free partial flank portion is exclusively from 0.1 μm to 100 μm exclusive; and
above the lower limit spatial wavelength and below the upper limit spatial wavelength, an effective roughness of the defect-free partial flank portion is less than 10 nm.

2. The mirror of claim 1, wherein the effective roughness of the defect-free partial flank portion above the lower limit spatial wavelength is less than 3 nm.

3. The mirror of claim 2, wherein, for each overall flank portion, the defect-free partial flank portion makes up at least 95% of an extent of the overall flank portion.

4. The mirror of claim 3, wherein a maximum slope variation of structures of the defect-free partial flank portion is no more than 200°/μm.

5. The mirror of claim 1, wherein, for each overall flank portion, the defect-free partial flank portion makes up at least 95% of an extent of the overall flank portion.

6. The mirror of claim 5, wherein a maximum slope variation of structures of the defect-free partial flank portion is no more than 200°/μm.

7. The mirror of claim 1, wherein a maximum slope variation of structures of the defect-free partial flank portion is no more than 200°/μm.

8. The mirror of claim 1, wherein the defect-free partial flank portion is manufactured by a subtractive method and/or by an additive method.

9. The mirror of claim 1, wherein the effective roughness of the defect-free partial flank portion above the lower limit spatial wavelength is less than 0.3 nm.

10. The mirror of claim 9, wherein a maximum slope variation of structures of the defect-free partial flank portion is no more than 150°/μm.

11. The mirror of claim 1, wherein a maximum slope variation of structures of the defect-free partial flank portion is no more than 150°/μm.

12. The mirror of claim 1, wherein, in a plan view, an area of the overall flank portions define is at most 5% of an area of the overall reflection surface of the mirror.

13. The mirror of claim 12, wherein, for each overall flank portion, an angle between the overall flank portion and the first grating level is less than 90°.

14. The mirror of claim 11, wherein, for each overall flank portion, an angle between the overall flank portion and the first grating level is less than 90°.

15. The mirror of claim 1, wherein, for each overall flank portion, an angle between the overall flank portion and the first grating level is between 5° and 80°.

16. An optical unit configured to guide illumination light along a path to an object field in an object plane, the optical unit comprising:
a mirror according to claim 1,
wherein the mirror is along the path of the illumination light to the object field.

17. An optical system, comprising:
an illumination optical unit configured to guide illumination light along a path to an object field in an object plane, the illumination optical unit comprising a mirror according to claim 1 along the path of the illumination light to the object field; and
a projection optical unit configured to project the object field to an image field in an image plane.

18. An illumination system, comprising:
an EUV light source configured to produce EUV light;
an illumination optical unit configured to guide the EUV light along a path to an object field in an object plane,
wherein the illumination optical unit comprises a mirror according to claim 1 along the path of the EUV light to the object field.

19. A projection exposure apparatus, comprising:
an EUV light source configured to produce EUV light;
an illumination optical unit configured to guide the EUV light along a path to an object field in an object plane, the illumination optical unit comprising a mirror according to claim 1 along the path of the EUV light to the object field; and
a projection optical unit configured to project the object field to an image field in an image plane.

20. A method of using a projection exposure apparatus comprising an illumination optical unit and a projection optical unit, the method comprising:
using the illumination optical unit to illuminate structures of an object in an object field of an object plane; and
using the projection optical unit to project the illuminated structures of the object in the object field to an image field in an image plane,
wherein the illumination optical unit comprises a mirror according to claim 1.
